(19) United States
(12) Patent Application Publication
(10) Pub. No.: US 2009/0226715 A1
(43) Pub. Date: Sep. 10, 2009

(54) COATED ARTICLE AND METHOD OF MAKING THE SAME

(75) Inventors: Leonid C. Lev, West Bloomfield, MI (US); Erkan Konca, Altindag (TR); Michael J. Lukitsch, Marysville, MI (US)

Correspondence Address: Julia Church Dierker;Dierker & Associates, P.C., 3331 W. Big Beaver Road, Suite 109, Troy, MI, 48084-2813, US

(73) Assignee: GM GLOBAL TECHNOLOGY OPERATIONS, INC., Detroit, MI (US)

(21) Appl. No.: 12/042,227

(22) Filed: Mar. 4, 2008

(51) Int. Cl. B32B 15/04; B05D 1/36; C23C 16/44

(52) U.S. Cl. 428/336; 428/457; 428/472.2; 428/665; 427/445; 427/405; 427/255.28

(57) ABSTRACT

A coated article includes a substrate and a substantially pure metal layer coated thereon. The substantially pure metal layer is configured to enhance the strength of the underlying substrate. A method is also disclosed for making a coated article by providing a substrate and coating a substantially pure metal layer thereon.

### TECHNICAL FIELD

The present disclosure generally relates to coated articles, and more particularly, to surface-coated articles for tooling of hard and/or tough materials and a method for making the same.

### BACKGROUND

Various grades of cemented carbide are often used as a material for forming cutting tools, drilling tools, tapping tools, and other similar machining or working tools. The grade of the cemented carbide is generally selected based on its grain size and binder content, which dictate the level of the material's wear resistance and toughness. These two factors tend to influence the life span of the substrate. Tungsten carbide (WC) is most often used as the carbide for the substrate for these tools.

To make the substrate, the carbide is “cemented” by dispersing the carbide in a metal binder material, such as iron, nickel or cobalt and then applying a liquid phase sintering process to the carbide material. If tungsten carbide is selected with a cobalt (Co) binder, for example, the resulting material is often referred to as a WC-Co system.

Cemented carbide is a substantially hard material that is useful in tooling of hard and/or tough materials (e.g., aluminum alloys, cast iron, carbon steel or stainless steel). The cemented carbide, however, tends not to exhibit at least some plastic deformation under standard operating conditions, and thus may be susceptible to cracking when exposed to repeated use. Generally, the strength of an article/tool having a cemented carbide substrate is governed by the distribution of the largest flaws or cracks present in the article. Since the largest flaws or cracks tend to formulate at the surface of the substrate, fracturing of the article/tool tends to be surface initiated. In response to wear and tear on the article/tool (usually from repeated use), the flaws or cracks tend to increase both in size and in number, thus making the article/tool more susceptible to fracture. Thus, the strength and hardness of the article or tool may diminish over time, and inadequate tooling performance may result.

### SUMMARY

A coated article includes a cemented carbide substrate and a substantially pure metal layer established thereon. The substantially pure metal layer is configured to enhance the strength of the substrate. A hardening layer may also be established on the substantially pure metal layer.

Also disclosed herein is a method for making a coated article. Generally, the method includes providing a cemented carbide substrate and establishing a substantially pure metal layer thereon. The substantially pure metal layer is configured to enhance the strength or toughness of the substrate. A hardening layer may be established on the substantially pure metal layer if desired.

### BRIEF DESCRIPTION OF THE DRAWINGS

Features and advantages of embodiments of the present disclosure will become apparent by reference to the following detailed description and the drawings, in which like reference numerals correspond to similar, though perhaps not identical components. For the sake of brevity, reference numerals or features having a previously described function may or may not be described in connection with other drawings in which they appear.

FIG. 1 is a semi-schematic cross-sectional cutaway view of an embodiment of the coated article, where a toughening layer is coated on the surface of the substrate;

FIG. 2 is a semi-schematic cross-sectional cutaway view of another embodiment of the coated article, where a toughening layer is coated on the surface of the substrate, and a hardening layer is coated on the toughening layer;

FIGS. 3A and 3B are graphical representations of microscope images of a Rockwell C indentation on an uncoated WC-Co sample substrate at 10× and 40× magnification levels, respectively;

FIGS. 4A and 4B are graphical representations of microscope images of a Rockwell C indentation on a WC-Co sample substrate having a layer of Cr coated thereon at 10× and 40× magnification levels, respectively; and

FIGS. 5A and 5B are graphical representations of microscope images of a Rockwell C indentation on a WC-Co sample substrate having a layer of Cr coated thereon at 10× and 40× magnification levels, respectively, where a portion of the Cr layer is partially removed.

### DETAILED DESCRIPTION

Embodiments of the coated article disclosed herein advantageously have enhanced strength when used as a tool for cutting or forming hard materials, such as aluminum alloys, cast iron, carbon steel and stainless steel. It is believed that the enhanced strength minimizes wear and tear of the article during operation, for example, when used in tooling of hard and/or tough materials. The surface of the article (e.g., tools, such as drills, taps, etc.) is coated with a thin layer of substantially pure metal (i.e., the toughening layer), where the metal is selected from a substantially pure metal or a substantially pure alloy composed of two or more metals exhibiting high levels of strength enhancing properties.

A second layer may be introduced on the thin metal layer to improve the hardness of the article and, thus, protect the article from additional wear and tear.

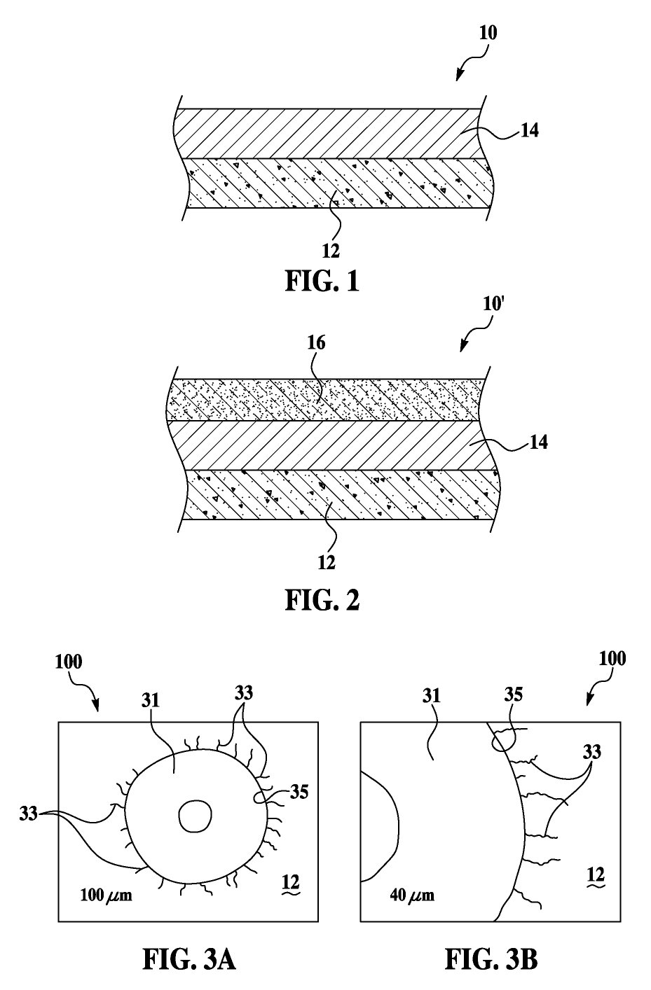

With reference now to the drawings, FIG. 1 represents a semi-schematic cross-sectional cutaway view of an article 10, which in a non-limiting example embodiment is a tool. The article 10 includes a substrate or body 12 and a metallic toughening layer 14 (i.e., substantially pure metal layer) coated or deposited thereon. The substrate 12 may have any desirable shape, geometry, and/or configuration and is adaptable for use in a variety of tooling and/or machining operations. Likewise, the toughening layer 14 is adapted to the configuration and geometry of the substrate 12.

As shown in FIG. 1, the substrate 12 and the toughening layer 14 are depicted as two separate, about equally sized layers in thickness. It should be noted, however, that the article 10 shown in FIG. 1 may not be to scale, and that the substrate 12 and the toughening layer 14 typically have different thicknesses. The substrate 12 and the layer 14 are also shown as two separate layers. It is to be understood that, generally, the substrate 12 and the layer 14 are compatible at their interface although a clear visual distinction between them may not be noticeable.

The substrate 12 is generally made of a super-fine particle cemented carbide including WC (tungsten carbide) as its main component and may be described as generally brittle in comparison to the stress and deformation resistance of tougher materials that the article 10 may come into contact with. Non-limiting examples of other suitable brittle substrates 12 include silicon carbide (SiC), aluminum oxide (Al₂O₃), cubic boron nitride (cBN), and/or the like, and/or combinations thereof.

Generally, the mechanical properties of the substrate 12 material (e.g., cemented carbide) depend, as least in part, on the amount of binder(s) used in them, as well as the type of binder(s) used. The mechanical properties of the substrate 12, with respect to the resistance to stress and deformation, are generally characterized according to hardness (H, measured in HRA or HV units); fracture toughness (K_{1C}, measured in MPaM^{1/2}); transverse rupture strength (TRS, measured in GPa); and Young's modulus (measured in GPa). In an embodiment, the substrate 12 is a cemented carbide selected from those having a fracture toughness ranging from about 5.6 MPaM^{1/2} to about 8.7 MPaM^{1/2}, a hardness ranging from about 91 HRA to about 94 HRA (or from about 1500 HV to about 1930 HV), a transverse rupture strength ranging from about 3.2 GPa to about 4.4 GPa, and a Young's modulus ranging from about 520 GPa to about 630 GPa. In another embodiment, the grain size of the cemented carbide ranges from about 0.2 microns to about 10 microns in granular diameter. In a non-limiting example, the grain size of the cemented carbide is 3 microns.

Suitable cemented carbides that may be used herein includes Grade MF07, MF10, MF20, MF30, SF10, TF15, and HTi10, all of which are commercially available from Mitsubishi Materials Corp., Tokyo, Japan.

In an embodiment, the cemented carbide further includes from about 6 wt % to about 30 wt % cobalt as a metallic binding material, with the remainder being cemented carbide (WC). It is to be understood that other binder metal material may be used, such as iron, nickel, or other metals and metal alloys, or combinations thereof.

When continuously contacted with hard and/or tough materials such as aluminum alloys, cast iron, carbon steel or stainless steel, the cemented carbide substrate 12 may break down over time and cracking may begin to form. The cracking of the substrate 12 (also referred to herein as “wear and tear”) weakens the durability of the article and may result in fracturing of the article 10 and/or poor performance of the article 10. The toughening layer 14 is coated or deposited on the substrate 12 to enhance the strength or toughness of the substrate 12, thereby potentially improving the overall lifespan of the article 10. The toughening layer 14 may also cure existing defects (such as cracks) in the substrate 12, in addition to enhancing the material's toughness.

In an embodiment, the toughening layer 14 is made of substantially completely pure metal. In another embodiment, the toughening layer 14 is made of a substantially completely pure alloy composed of two or more metals.

In an embodiment, and as shown in FIG. 1, the toughening layer 14 may be a single layer of a substantially completely pure metal or an alloy of two or more metals. In another embodiment, the toughening layer 14 may include a plurality of layers (not shown in FIG. 1), where each layer is made of different substantially completely pure metals or alloys. In still another embodiment, the toughening layer 14 may include a plurality of layers (not shown in FIG. 1), where at least one of the layers is made of the substantially completely pure metal or alloy. As used herein, the phrase “substantially completely pure metal” refers to a metal having impurities, the amount of which is so minimal that it can barely be accounted for. Also as used herein, the phrase “substantially completely pure alloy composed of two or more metals” refers to an alloy of two or more metals having impurities, the amount of which is so minimal that is can barely be accounted for. It is to be understood that the amount of impurities present in the metal or alloy does not deleteriously affect the toughness and plastic deformation capability of the metal.

It is also to be understood that it may be desirable to deposit the toughening layer 14 directly on the substrate 12 in the absence of or with minimal amounts of debris, oxides or other impurities. It is believed that such conditions enable the toughening layer 14 to readily adhere to the substrate 12 through atomic bonding, and thus no additional adhesive layer or material is utilized to bind the toughening layer 14 to the substrate 12. It is to be understood that some metals or metal alloys are capable of adhering to the substrate 12 regardless of the deposition conditions. In still other embodiments, adhesion between the toughening layer 14 and the substrate 12 may be improved by including additional intermediate layer(s) (not shown) that exhibit adhesive properties toward both the substrate 12 and the toughening layer 14.

Desirable metals or metal alloys for the toughening layer 14 are those exhibiting high levels of toughness and resistance to cracking, as measured by their fracture toughness. In an embodiment, the toughening layer 14 is desirably selected to have a fracture toughness of at least 50 MPaM^{1/2}. In another embodiment, the toughening layer 14 is selected to have a fracture toughness ranging from about 50 MPaM^{1/2} to about 150 MPaM^{1/2}. It is to be understood that the fracture toughness may be greater, depending, at least in part, on the desirable strength for the article 10.

The toughening layer 14 may be deposited on any desirable area of the substrate 12. As a non-limiting example, the toughening layer 14 may be established on the substrate 12 such that areas of the article 10 that will ultimately contact the external material to be tooled contain the layer 14. It is to be understood, however, that portions of the substrate 12 having the toughening layer 14 deposited thereon may not necessarily be the area(s) at which fracturing takes place. Thus, it may be desirable to coat those area(s) prone to fracture and/or the entire surface area of the substrate 12 with the layer 14.

Suitable metals for the layer 14 include nickel, titanium, chromium, tungsten, zirconium, steel, iron, or other metals of similar strength enhancing properties. Suitable alloys for the layer 14 include alloys of the previously listed metals. Non-limiting examples of suitable alloys for the layer 14 include a titanium nickel alloy and a nickel chromium alloy. The thickness of the toughening layer 14 may range from about 3 microns to about 12 microns in thickness. In a non-limiting example, the thickness ranges from about 5 microns to about 7 microns. A thickness of 6 microns may be desirable in some applications. The toughening layer 14 is coated or deposited on the surface of the substrate 12 using any suitable coating process. Examples of such processes include, but are not limited to physical vapor deposition (PVD) methods (such as ion plating, cathodic arc deposition, evaporative deposition, electron beam physical vapor deposition, pulsed laser deposition, and sputter deposition), electroplating, or other vacuum coating processes.

With reference now to FIG. 2, a semi-schematic cross-sectional cutaway view of another embodiment of the article 10′ is depicted. According to FIG. 2, the article 10′ includes a substrate or body 12, an intermediate toughening layer 14 coated or deposited on the substrate 12 and an outer hardening layer 16 coated or deposited on the surface of the toughening layer 14. Similar to the description of FIG. 1, the substrate 12 and the layers 14, 16 of FIG. 2 are depicted as three separate, about equally sized layers in thickness. However, article 10′ may not be represented to scale, and the substrate 12 and the layers 14, 16 are typically different in thickness. Again, it is to be understood that, generally, the substrate 12 and the layers 14, 16 will be compatible at their respective interfaces although a clear visual distinction between the substrate 12 and the layers 14, 16 may not be noticeable.

Like that of the embodiment shown in FIG. 1, the substrate 12 is generally made of cemented tungsten carbide with cobalt as its metallic binding material, and the toughening layer 14 is generally made of substantially completely pure metal or an alloy of two or more substantially completely pure metals, where the amount of impurities is minimal. As previously described, the toughening layer 14 may be deposited on the substrate 12 such that any desirable area(s) of the article 10′ contain the layer 14, for example, those areas that will ultimately contact the external material to be tooled, those areas that are prone to fracture, or on the entire surface area of the substrate 12.

The hardening layer 16 is coated or deposited on the surface of the toughening layer 14 to enhance the hardness of the article 10′ and to potentially improve its overall lifespan. Suitable materials for the hardening layer 16 are chosen from those materials exhibiting values of hardness that make the material capable of withstanding heavy impact with other hard materials, such as pure iron or alloys thereof. Desirable materials for the hardening layer 16 are those exhibiting hardness levels in the range of about 20 GPa to about 100 GPa. In an embodiment, the materials for the hardening layer 16 include titanium nitride (TiN), diamond, titanium carbide (TiC), chromium nitride (CrN), and/or combinations thereof.

The hardening layer 16 has a thickness in the range of about 2 microns to about 12 microns and is deposited on the toughening layer 14, generally in the area(s) of the article 10′ that will contact another material in operation and/or that are prone to fracture. In non-limiting examples, the thickness ranges from about 2 microns to about 10 microns or from about 8 microns to about 12 microns. The hardness layer 16 may cover part of, or the entire, surface area of the toughening layer 14.

The hardening layer 16 is coated or deposited on the surface of the toughening layer 14 using any suitable coating process. Non-limiting examples of such processes include a Hot Filament Chemical Vapor Deposition (HFCVD) method, or a plasma assisted chemical vapor deposition (PACVD) method, both of which are methods for depositing diamond, for example, on a substrate.

To further illustrate embodiment(s) of the present disclosure, examples are given herein. It is to be understood that these examples are provided for illustrative purposes and are not to be construed as limiting the scope of the disclosed embodiment(s).

### EXAMPLES

Referring now to FIGS. 3-5, graphical representations of microscope images of coated and uncoated substrates are shown. For all of the representations shown in FIGS. 3-5, coupons (100, 100′, 100″ shown in FIGS. 3A, 4A, and 5A respectively) were constructed out of cemented tungsten carbide having a composition of about 15 wt % Co and an average WC grain size of about 3 microns. Rockwell C indentations were performed on each of the coupon 100, 100′, 100″ samples. The Rockwell hardness test is a method for testing the hardness, strength and/or fracture toughness of a test specimen or sample. In this test, a steel or diamond indenter of a selected size and shape (known as a Braile Indenter) is pressed against the test specimen (coupons 100, 100′, 100″ in these examples) and the resulting indentation depth is measured. The hardness number was calculated from the indentation depth. In general, with harder materials, the hardness number will be higher.

For each of the follow samples, the sample was exposed to a minor load of about 10 kgf. Then a major load (150 kgf was used for the samples described herein below) was applied to the coupons 100, 100′, 100″ to create a full indentation. The graphical representations in FIGS. 3-5 are microscope images of the respective coupons 100, 100′, 100″ at 10× and 40× power levels after the indentations were made.

### Sample 1

A test sample of the coupon 100 composed of an uncoated cemented tungsten carbide substrate 12 was subjected to a load of 150 kgf by an indenter in accordance with the Rockwell C Indentation test as described above. A generally circular indentation 31 was formed into the substrate 12 upon impact from the indenter. Microscope images of the coupon 100 were taken at 10× and 40× magnification levels, and graphical representations of such images are depicted in FIGS. 3A and 3B, respectively.

As shown in both FIGS. 3A and 3B, the impact of the 150 kgf load of the indenter caused the substrate 12 to weaken and crack. The weakened areas are shown in the representations as cracks 33 projecting from the edge 35 of the indentation 31 and into the substrate 12. The graphical representation of a magnified picture of a portion of the indentation 31 showing the cracks 33 is shown in FIG. 3B. These cracks 33 diminish the strength or toughness of the substrate 12 and will, most likely, cause the substrate 12 to wear down further over time.

### Sample 2

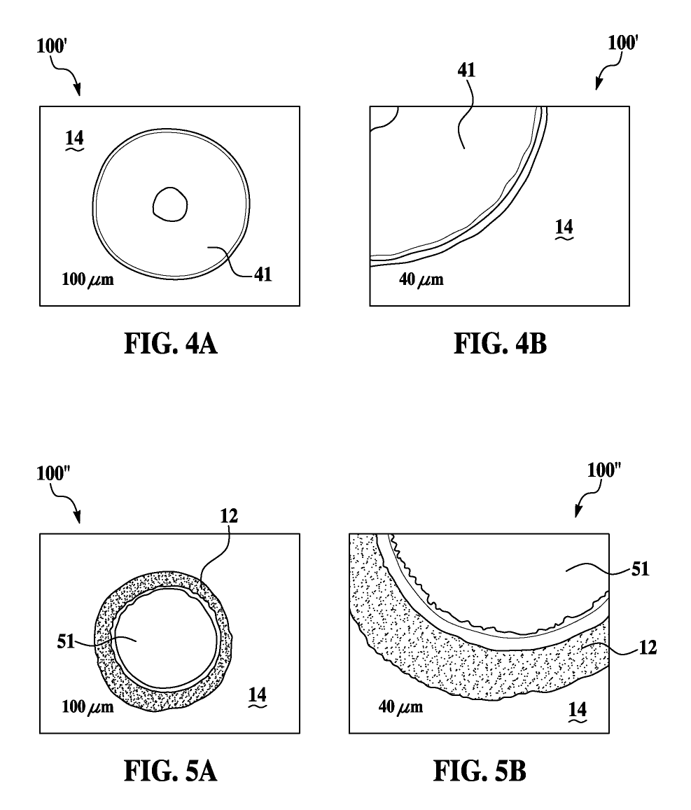

FIGS. 4A and 4B are graphical representations of microscope images (with magnification levels of 10× and 40×, respectively) of a test sample of the coupon 100′ having a substrate (not shown) coated with a toughening layer 14 and then subjected to a load of 150 kgf by an indenter in accordance with the Rockwell C Indentation test. The substrate was made of WC-Co, and the toughening layer 14 was about 6.3 microns thick and was substantially pure chromium (Cr) with impurities present in an amount less than 1%. A circular indentation 41 was formed on the surface of the toughening layer 14 and penetrated into the underlying substrate. As shown in both FIGS. 4A and 4B, substantially no weaknesses or cracks formed in the coupon 100′ under the impact of the indenter by the 150 kgf load.

### Sample 3

FIGS. 5A and 5B are graphical representations of microscope images (at magnification levels of 10× and 40×, respectively) of a test sample of the coupon 100″ having a WC-Co substrate 12 coated with a toughening layer 14 (similar to Sample 2). The toughening layer 14 was about 6.3 microns in thickness and made of substantially pure chromium (Cr) with impurities present in an amount less than 1%.

The coupon 100″ was subjected to a load of 150 kgf by an indenter in accordance with the Rockwell C Indentation test. A circular indentation 51 was formed on the surface of the toughening layer 14. To ensure that the toughening layer 14 did not obscure any weaknesses or cracks, the toughening layer 14 was partially removed by polishing, thereby exposing some of the underlying substrate 12. The graphical representations of the resulting microscopic images are shown in FIGS. 5A and 5B. Substantially no weaknesses or cracks were observed in the WC-Co substrate 52 as depicted in the images.

Introduction of a substantially pure metal toughening layer 14 on the surface of a substrate 12 for an article 10, 10′ used, for example, in tooling, improves the article's strength upon impact against a strong and/or hard material. The toughening layer 14 also acts to cure prior existing defects in the substrate 12. The article 10, 10′, thus, advantageously has improved durability and a potentially longer lifespan of operational use. With the introduction of a hardening layer 16 disposed on the toughening layer 14, the article 10, 10′ may furthermore be protected against scratching, gouging and/or other effects caused from typical operation wear and tear, in addition to having improved strength as a result of the toughening layer 14.

While several embodiments have been described in detail, it will be apparent to those skilled in the art that the disclosed embodiments may be modified. Therefore, the foregoing description is to be considered exemplary rather than limiting.

1. A coated article, comprising:
a substantially brittle substrate; and
a substantially pure metal layer established on the brittle substrate, the substantially pure metal layer configured to enhance strength of the substantially brittle substrate.

2. The coated article as defined in claim 1 wherein the brittle substrate is cemented carbide, silicon carbide, aluminum oxide, cubic boron nitride, and combinations thereof.

3. The coated article as defined in claim 2 wherein the cemented carbide includes from about 6% to about 30% cobalt, and from about 70% to about 94% tungsten carbide.

4. The coated article as defined in claim 1 wherein the substantially pure metal layer has a thickness ranging from about 3 microns to about 12 microns.

5. The coated article as defined in claim 1, further comprising a hardening layer established on the substantially pure metal layer.

6. The coated article as defined in claim 5 wherein the hardening layer is selected from a diamond coating, a TiN coating, a TiC coating, a CrN coating, and combinations thereof.

7. The coated article as defined in claim 5 wherein the hardening layer has a thickness ranging from about 2 microns to about 10 microns.

8. The coated article as defined in claim 1 wherein the substantially pure metal layer substantially prevents cracking in the substantially brittle substrate, substantially cures existing defects in the substantially brittle substrate, or combinations thereof.

9. The coated article as defined in claim 1 wherein the substantially pure metal layer includes a substantially completely pure metal or a substantially completely pure alloy composed of at least two substantially pure metals.

10. The coated article as defined in claim 9 wherein the substantially pure metals are selected from nickel, titanium, chromium, tungsten, steel, iron, zirconium, and combinations thereof.

11. The coated article as defined in claim 1 wherein the substantially pure metal in the substantially pure metal layer exhibits a fracture toughness of at least about 50 MPa/m².

12. A tool, comprising:
a tungsten carbide-cobalt composite substrate;
a substantially pure metal layer established on the tungsten carbide-cobalt composite substrate; and
a hardening layer established on the substantially pure metal layer.

13. The tool as defined in claim 12 wherein a substantially pure metal or a substantially pure metal alloy in the substantially pure metal layer exhibits a fracture toughness ranging from about 50 MPa/m² to about 150 MPa/m².

14. The tool as defined in claim 13 wherein the substantially pure metal is selected from nickel, titanium, chromium, tungsten, steel, iron, zirconium, alloys thereof, and combinations thereof.

15. The tool as defined in claim 12 wherein the hardening layer is selected from a diamond coating, a TiN coating, a TiC coating, a CrN coating, and combinations thereof.

16. The tool as defined in claim 12 wherein the substantially pure metal layer substantially prevents cracking in the tungsten carbide-cobalt composite substrate, substantially cures existing defects in the tungsten carbide-cobalt composite substrate, or combinations thereof.

17. A method for making a coated article, comprising:
providing a substantially brittle substrate; and
establishing a substantially pure metal layer on the substantially brittle substrate, wherein the substantially pure metal layer is configured to enhance strength of the substantially brittle substrate.

18. The method as defined in claim 17 wherein the substantially pure metal layer includes a substantially completely pure metal, and wherein the substantially completely pure metal is selected from nickel, titanium, chromium, tungsten, steel, iron, zirconium, alloys thereof, and combinations thereof.

19. The method as defined in claim 17 wherein the substantially pure metal layer includes a substantially pure metal alloy composed of two or more metals selected from titanium, chromium, tungsten, steel, iron, and zirconium.

20. The method as defined in claim 17, further comprising establishing a hardening layer on the substantially pure metal layer.

21. The method as defined in claim 20 wherein establishing the hardening layer is accomplished by chemical vapor deposition.
